(19) United States
(12) Patent Application Publication
(10) Pub. No.: US 2025/0105237 A1
(43) Pub. Date: Mar. 27, 2025

(54) SEMICONDUCTOR PACKAGE ASSEMBLY

(71) Applicant: MEDIATEK INC., Hsinchu City (TW)

(72) Inventors: Chung-Min YANG, Hsinchu City (TW); Che-Hung KUO, Hsinchu City (TW)

(21) Appl. No.: 18/893,113

(22) Filed: Sep. 23, 2024

Related U.S. Application Data
(60) Provisional application No. 63/584,925, filed on Sep. 25, 2023.

(51) Int. Cl. H01L 25/18; H01L 23/00; H01L 23/498; H01L 23/528; H01L 25/065; H05K 1/18; H10B 80/00

(52) U.S. Cl. CPC H01L 25/18; H01L 23/5283; H01L 24/16; H01L 25/0652; H01L 25/0657; H10B 80/00; H01L 23/49866; H01L 24/48; H01L 24/73; H01L 2224/16225; H01L 2224/48227; H01L 2224/73257; H01L 2225/0651; H01L 2225/06517; H01L 2225/06548; H01L 2225/06562; H01L 2924/1431; H01L 2924/1436; H05K 1/181

(57) ABSTRACT

A semiconductor package assembly is provided. The semiconductor package assembly includes first and a second semiconductor dies. The first semiconductor die has a first surface and a second surface opposite the first surface. The first semiconductor die includes a first interface and a second interface. The second interface is arranged beside the first interface. The second interface is farther from the corresponding first edge of the first semiconductor die than the first interface. The second semiconductor die is stacked on the first semiconductor die. The semiconductor package assembly further includes a first conductive bump and a second conductive bump. The first conductive bump is disposed on the first surface of the first semiconductor die. The second conductive bump is disposed on the second surface of the first semiconductor die. The second semiconductor die is electrically coupled to the first semiconductor die by the second interface.

### CROSS REFERENCE TO RELATED APPLICATIONS

This application claims the benefit of U.S. Provisional Application No. 63/584,925, filed on Sep. 25, 2023, the entirety of which is incorporated by reference herein.

### BACKGROUND OF THE DISCLOSURE

### Field of the Disclosure

The present disclosure relates to a semiconductor package assembly, and, in particular, to an interface floorplan for a package-on-package (POP) semiconductor package.

### Description of the Related Art

With the increasing demand for smaller devices with more functionality, package-on-package (POP) technology has become increasingly popular. PoP technology vertically stacks two or more packages and minimizes the track lengths between different components, such as a controller and a memory device. This provides better electrical performance, since shorter routing of interconnections yields faster signal propagation and reduced noise and cross-talk defects.

Although existing semiconductor package assemblies have generally been adequate, they are not satisfactory in every respect. For example, it is difficult to fulfill the interface requirements for integrating different components into a single package. Therefore, there is a need to further improve semiconductor package assemblies to provide greater flexibility in interface design.

### BRIEF SUMMARY OF THE INVENTION

An embodiment of the present disclosure provides a semiconductor package assembly. The semiconductor package assembly includes a first semiconductor die and a second semiconductor die. The first semiconductor die has a first surface and a second surface. The second surface is opposite the first surface. The first semiconductor die includes, a first interface and a second interface. The second interface is arranged beside the first interface. The second interface is farther from the corresponding first edge of the first semiconductor die than the first interface. The second semiconductor die is stacked on the first semiconductor die. The semiconductor package assembly further includes a first conductive bump and a second conductive bump. The first conductive bump is disposed on the first surface of the first semiconductor die. The second conductive bump is disposed on the second surface of the first semiconductor die. The second semiconductor die is electrically coupled to the first semiconductor die by the second interface.

An embodiment of the present disclosure provides a semiconductor package assembly. The semiconductor package assembly includes a fan-out package and a memory package. The fan-out package includes a first routing structure, a second routing structure and a top semiconductor die. The first routing structure and the second routing structure are stacked on each other. The top semiconductor die is disposed between the first routing structure and the second routing structure. The top semiconductor die includes a first interface and a second interface. The first interface is arranged on a first edge of the top semiconductor die. The second interface is arranged adjacent to the first interface. The second interface is farther from the corresponding first edge of the top semiconductor die than the first interface. The memory package is disposed on the fan-out package. A base is electrically coupled to the first interface by at least the second routing structure. The memory package is electrically coupled to the second interface by the first routing structure rather than the second routing structure.

### BRIEF DESCRIPTION OF THE DRAWINGS

The present disclosure can be more fully understood by reading the subsequent detailed description and examples with references made to the accompanying drawings, wherein:

FIG. 1A is a cross-sectional view of a semiconductor package assembly in accordance with some embodiments of the disclosure;

FIG. 1B is a partial enlarged view of FIG. 1A;

FIG. 2 is a perspective bottom view of the semiconductor package assembly of FIG. 1A in accordance with some embodiments of the disclosure, showing the arrangement of interfaces of a semiconductor die and through via (TV) interconnects of a bottom package and the arrangement of conductive structures of a top package stacked on the bottom package;

FIG. 3 is a cross-sectional view of a semiconductor package assembly in accordance with some embodiments of the disclosure;

FIG. 4 is a cross-sectional view of a semiconductor package assembly in accordance with some embodiments of the disclosure;

FIG. 5 is a perspective bottom view of the semiconductor package assembly of FIG. 4 in accordance with some embodiments of the disclosure, showing the arrangement of interfaces of a semiconductor die and through via (TV) interconnects of a bottom package and the arrangement of conductive structures of a top package stacked on the bottom package;

FIG. 6 is a cross-sectional view of a semiconductor package assembly in accordance with some embodiments of the disclosure;

FIG. 7 is a cross-sectional view of a semiconductor package assembly in accordance with some embodiments of the disclosure; and

FIG. 8 is a cross-sectional view of a semiconductor package assembly in accordance with some embodiments of the disclosure.

### DETAILED DESCRIPTION OF THE INVENTION

The following description is made for the purpose of illustrating the general principles of the disclosure and should not be taken in a limiting sense. The scope of the disclosure is best determined by reference to the appended claims.

Advanced integrated circuit ((IC) devices have become increasingly multifunctional and have been scaled down in size. Although the scaling down process generally increases production efficiency and lowers the associated costs, it has also increased the complexity of processing and manufacturing IC devices. For example, Fin Field-Effect Transistors (FinFETs) have been introduced to replace planar transistors. Among these FinFETs, gate-all-around (GAA) structures such as nanosheet or nanowire metal-oxide-semiconductor field-effect transistors (MOSFET) have been developed to possess excellent electrical characteristics, such as better power performance and area scaling compared to the current FinFET technologies. Furthermore, back-side power technology is used in gate-all-around (GAA) structures to decrease second routing, so as to decrease back end of line (BEOL) capacitance and IR drop, thereby improving performance of IC. Although existing integrated circuit (IC) devices are generally adequate, they are not satisfactory in every respect. For example, in the package-on-package (POP) semiconductor package assembly, it is a challenge to arrange enough input/output (I/O) interfaces in the limited peripheral edges of a semiconductor die. Therefore, there is a need to utilize the semiconductor die having back-side power rails into a PoP semiconductor package assembly.

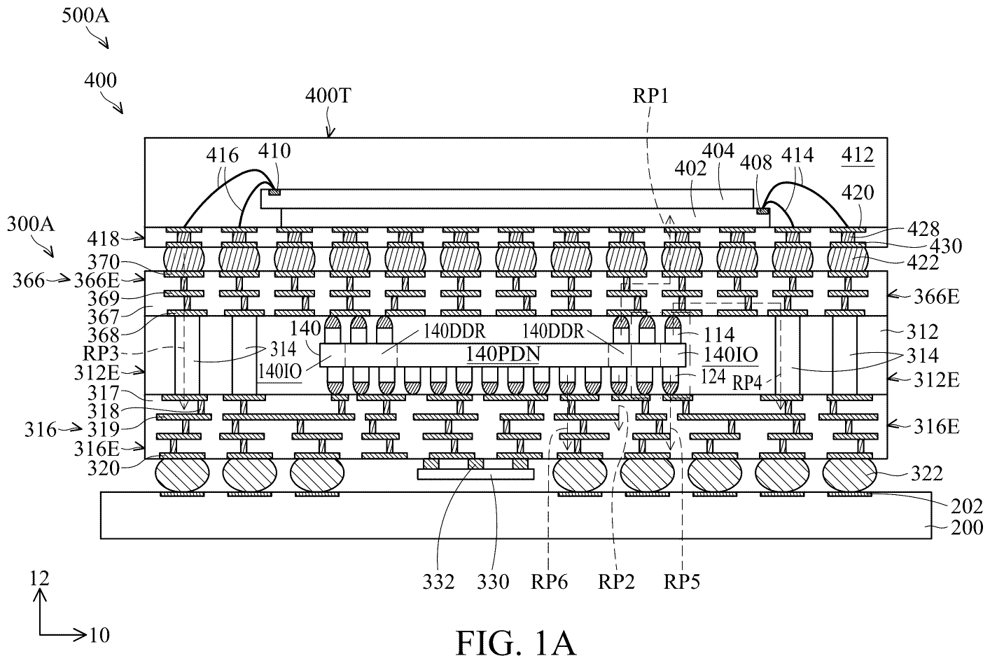

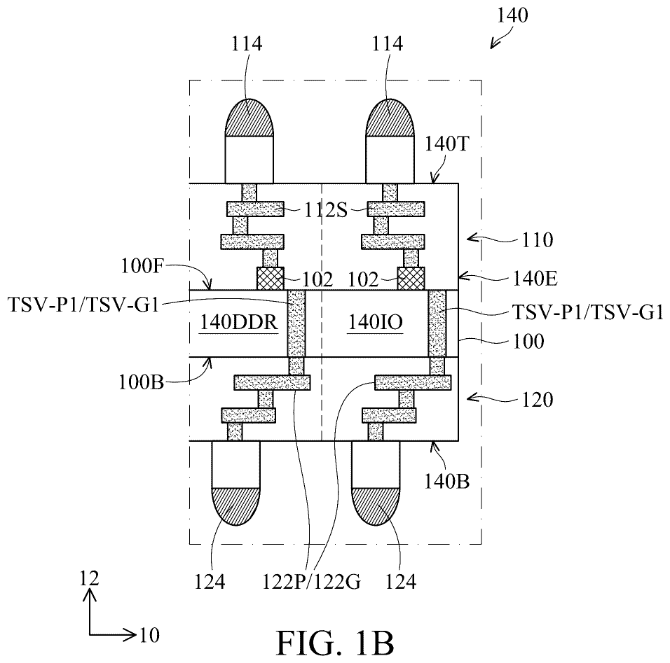

FIG. 1A is a cross-sectional view of a semiconductor package assembly 500A in accordance with some embodiments of the disclosure. FIG. 1B is a partial enlarged view of FIG. 1A. In some embodiments, the semiconductor package assembly 500A is a three-dimensional (3D) package-on-package (POP) semiconductor package assembly. The semiconductor package assembly 500A may include at least two vertically stacked wafer-level semiconductor packages mounted on a base 200. For example, as shown in FIG. 1A, in some embodiments, the semiconductor package assembly 500A includes a bottom package 300A and a top package 400 vertically (in the direction 12) stacked on the bottom package 300A. In some embodiments, the bottom package 300A includes a fan-out package such as a system-on-chip (SOC) package. The top package 400 includes a memory package such as a dynamic random access memory (DRAM) package. In some embodiments, the semiconductor package assembly 500A may not include the base 200; that is, the base 200 is external to the semiconductor package assembly 500A.

As shown in FIG. 1A, the base 200, for example a printed circuit board (PCB), may be formed of polypropylene (PP), Pre-preg, FR-4 and/or other epoxy laminate material. It should also be noted that the base 200 can be a single layer or a multilayer structure. A plurality of pads 202 and/or conductive traces (not shown) is disposed on the base 200. In one embodiment, the conductive traces may comprise signal trace segments or ground trace segments, which are used for the input/output (I/O) connections of the bottom package 300A and the top package 400. Also, the bottom package 300A is mounted directly on the conductive traces. In some other embodiments, the pads 202 are disposed on the base 200, connected to different terminals of the conductive traces. The pads 202 are used for the bottom package 300A that is mounted directly on them.

As shown in FIG. 1A, the bottom package 300A is mounted on the base 200 by a bonding process. The bottom package 300A is mounted on the base 200 using conductive structures 322. The bottom package 300A is a fan-out semiconductor package including a semiconductor die 140, a first routing structure 366, a second routing structure 316, through via (TV) interconnects 314 and the conductive structures 322. The conductive structures 322 are in contact with and electrically connected (or coupled) to the second routing structure 316. In addition, the conductive structures 322 are electrically connected (or coupled) to the pads 202 of the base 200. In some embodiments, the conductive structures 322 comprise a conductive ball structure such as a copper ball, a conductive bump structure such as a copper bump or a solder bump structure, or a conductive pillar structure such as a copper pillar structure.

The semiconductor die 140 disposed between the second routing structure 316 and the first routing structure 366. In some embodiments, the semiconductor die 140 has a first surface 140T, a second surface 140B opposite the first surface 140T, and an edge (edge surface) 140E connected (or coupled) between the first surface 140T and the second surface 140B. In some embodiments, the semiconductor die 140 is used in back-side power technology. In addition, the semiconductor die 140A may be fabricated by gate-all-around (GAA) processes. In some embodiments, the semiconductor die 140 may be electrically connected (or coupled) to the first routing structure 366 and the second routing structure 316 by conductive bumps (e.g., microbumps, controlled collapse chip connection (C4) bumps, or a combination thereof). The conductive bumps may be arranged on the first surface 140T and the second surface 140B of the semiconductor die 140.

In some embodiments, the semiconductor die 140 includes a semiconductor substrate 100, one or more electronic components 102, a first interconnect structure 110, a second interconnect structure 120 and conductive bumps 114, 124, as shown in FIG. 1B.

The semiconductor substrate 100 has a front surface 100F and a back surface 100B. In some embodiments, the material of the semiconductor substrate 100 includes Si, SiP, SiGe, SiC, SiPC, Ge, SOI—Si, SOI—SiGe, III-VI material, or a combination thereof.

The electronic component 102 is formed on the front surface 100F of the semiconductor substrate 100. In some embodiments, the electronic component 102 may be composed of transistors (e.g., GAA transistors), diodes, resistors, capacitors, and other active/passive devices, according to the requirements of design.

The front-side interconnect structure 110 is disposed on the front surface 100F of the semiconductor substrate 100. The back-side interconnect structure 120 is disposed on the back surface 100B of the semiconductor substrate 100 and opposite the front-side interconnect structure 110. The front-side interconnect structure 110 is separated from the back-side interconnect structure 120 by the semiconductor substrate 100. In some embodiments, the front-side interconnect structure 110 is formed covering and electrically connected to the electronic component 102. The back-side interconnect structure 220 is also electrically connected to the electronic component 102.

In some embodiments, the front-side interconnect structure 110 may include multiple dielectric layers and conductive routings (including signal routings 112) formed in the multiple dielectric layers. The conductive routings including conductive lines and vias (not shown) may be formed of copper or copper alloys, and may be formed using one or more damascene processes. The dielectric layers may include inter-layer dielectric (ILD) layers and inter-metal dielectric (IMD) layers.

In some embodiments, the front-side interconnect structure 110 may include signal routings 112S. The signal routings 112S are configured to transmit data signals, control signals, and other user signals.

In some embodiments, the back-side interconnect structure 120 may be similar to the front-side interconnect structure 110 and includes multiple dielectric layers and conductive routings (including power routings and ground routings) formed in the multiple dielectric layers. The number of dielectric layers in the front-side interconnect structure 110 and the back-side interconnect structure 220 may be the same or may be different.

In some embodiments, the back-side interconnect structure 120 may include power routings 122P and ground routings 122G. The power routings 122P may include positive power supply voltage VDD, ground power supply voltage VSS, overdriven voltage signals (e.g., signals greater than VDD), negative power supply voltage signals, and other power supply voltage signals. The ground routings are for grounding of the semiconductor die 140.

In some embodiments, the conductive routings (including the power routings 122P and the ground routings 122G) in the back-side interconnect structure 120 are electrically connected (or coupled) to the electronic component 102 by one or more through-substrate vias (TSV) passing through the semiconductor substrate 100. For example, the power routing 122P is electrically connected (or coupled) to the electronic component 102 by a through-substrate via TSV-P1. The through-substrate via TSV-P1 may have a first end that terminates at the front surface 100F and connected (or coupled) to the corresponding terminal of the electronic component 102. The through-substrate via TSV-P1 may have a second end that terminates at the back surface 100F of the semiconductor substrate 100 and connected (or coupled) to the power routing 122P. For example, the ground routing 122G is electrically connected (or coupled) to the electronic component 102 by a through-substrate via TSV-G1. The through-substrate via TSV-G1 may have a first end that terminates at the front surface 100F and connected (or coupled) to the corresponding terminal of the electronic component 102. The through-substrate via TSV-G1 may have a second end that terminates at the back surface 100F of the semiconductor substrate 100 and connected (or coupled) to the ground routing 122G.

The conductive bumps 114 are disposed on the first surface 140T of the semiconductor die 140. The conductive bumps 114 are electrically connected (or coupled) to the signal routings 112S of the front-side interconnect structure 110. In some embodiments, the conductive bumps 114 may serve as signal bumps.

The conductive bumps 124 are disposed on the second surface 140B of the semiconductor die 140. The conductive bumps 124 are electrically connected (or coupled) to the power routings 122P and the ground routings 122G of the back-side interconnect structure 120. In some embodiments, the conductive bumps 124 may serve as power bumps, ground bumps, or a combination thereof.

In some embodiments, the semiconductor die 140 includes a system-on-chip (SOC) die, a logic device, a memory device, a radio frequency (RF) device, the like, or any combination thereof. For example, the semiconductor die 140 may include a micro control unit (MCU) die, a microprocessor unit (MPU) die, a power management integrated circuit (PMIC) die, a global positioning system (GPS) device, a central processing unit (CPU) die, a graphics processing unit (GPU) die, an input-output (IO) die, a dynamic random access memory (DRAM) IP core, a static random-access memory (SRAM), a high bandwidth memory (HBM), the like, or any combination thereof.

In some embodiments, the first routing structure 366 includes a redistribution layer (RDL) structure or an interposer. For example, the first routing structure 366 may be an interposer 366. The first routing structure 366 is disposed on the first surface 140T of the semiconductor die 140. In addition, the first routing structure 366 is disposed above and in contact with the conductive bumps 114. In some embodiments, the first routing structure 366 includes one or more conductive traces 369, one or more vias 368 disposed in one or more dielectric layers 367 and contact pads 370. In some embodiments, the vias 368, the conductive traces 369 and the contact pads 370 include a conductive material, such as metals comprising copper, gold, silver, or other applicable metals. The dielectric layers 367 may include extra-low K (ELK) dielectrics and/or ultra-low K (ULK) dielectric. In addition, the dielectric layers 367 may include epoxy. It should be noted that the number of vias 368, the number of conductive traces 369, the number of contact pad 370 and the number of dielectric layers 367 shown in FIG. 1A are only an example and is not a limitation to the present disclosure.

In some embodiments, the second routing structure 316 includes an interposer, a redistribution layer (RDL) structure or a substrate. For example, the second routing structure 316 may be an interposer 316. The second routing structure 316 is disposed on the second surface 140B of the semiconductor die 140 and opposite the first routing structure 366. The second routing structure 316 is disposed below and in contact with the conductive bumps 124. In addition, the second routing structure 316 is disposed between the semiconductor die 140 and the base 200. As shown in FIG. 1B, the second routing structure 316 may include one or more conductive traces 319, one or more vias 318 disposed in one or more dielectric layers 317 and contact pads 320. The conductive traces 319 are electrically connected (or coupled) to the corresponding contact pads 320. The contact pads 320 are exposed to openings of the solder mask layer (not shown) and close to the base 200. The conductive elements 322 are disposed on and in contact with the corresponding the contact pads 320. Therefore, the conductive elements 322 are electrically connected (or coupled) between the contact pads 320 of the semiconductor package 300A and the pads 202 of the base 200. The semiconductor die 140 is electrically connected (or coupled) to the base 200 using the vias 318, the conductive traces 319 and the contact pads 320 of the second routing structure 316 and the corresponding conductive elements 322.

In some embodiments, the material of the vias 318, the conductive traces 319 and the contact pads 320 may be similar to the material of the vias 368, the conductive traces 369 and the contact pads 370. In addition, the material of the dielectric layers 317 may be similar to the material of the dielectric layers 367. It should be noted that the number of vias 318, the number of conductive traces 319, the number of contact pads 320 and the number of dielectric layers 317 shown in FIG. 1A are only an example and is not a limitation to the present disclosure.

The through via (TV) interconnects 314 are disposed on the routing structure 316 and beside the semiconductor die 140. The second routing structure 316 and the first routing structure 366 are in contact with opposite ends of the TV interconnects 314, respectively. The TV interconnects 314 are electrically connected (or coupled) between the vias 368, the conductive traces 369 and the contact pads 370 of the first routing structure 366 and the vias 318, the conductive traces 319 and the contact pads 320 of the second routing structure 316. In addition, the semiconductor die 140 and the TV interconnects 314 are sandwiched between the second routing structure 316 and the first routing structure 366 in the direction 12.

In some embodiments, the TV interconnects 314 may be electrically connected (or coupled) to the semiconductor die 140 using the vias 368 and the conductive traces 369 inside the first routing structure 366. In addition, the TV interconnects 314 may be electrically connected (or coupled) to the semiconductor die 140 using the vias 318 and the conductive traces 319 inside the second routing structure 316.

As shown in FIG. 1A, the bottom package 300A further includes a molding compound 312 disposed between and in contact with the first routing structure 366 and the second routing structure 316. The molding compound 312 may surround and is in contact with the semiconductor die 140, and the TV interconnects 314. The molding compound 312 may surround the conductive bumps 114, 124. In addition, the TV interconnects 314 pass through the molding compound 312. Opposite terminals of the conductive bumps 114, 124 may be exposed from the molding compound 312. In some embodiments, the molding compound 312 may be formed of a nonconductive material, such as an epoxy, a resin, a moldable polymer, or the like. The molding compound 312 may be applied while substantially liquid, and then may be cured through a chemical reaction, such as in an epoxy or resin. In some other embodiments, the molding compound 312 may be an ultraviolet (UV) or thermally cured polymer applied as a gel or malleable solid capable of being disposed around the semiconductor die 140, and then may be cured using a UV or thermally curing process. The molding compound 312 may be cured with a mold.

In some embodiments, edges 312E of the molding compound 312 are leveled with corresponding edges 366E of the first routing structure 366 and corresponding edges 316E of the second routing structure 316. Therefore, the edges 312E of the molding compound 312, the edges 366E of the first routing structure 366 and the edges 316E of the second routing structure 316 may collectively serve as package edges of the bottom package 300A.

As shown in FIG. 1A, the bottom package 300A further includes an electronic component 330 mounted on the second routing structure 316 opposite the semiconductor die 140. In some embodiments, the electronic component 330 has pads 332 on it and is electrically connected (or coupled) to the conductive traces 319 of the second routing structure 316. In some embodiments, the electronic component 330 is arranged between the conductive structures 322. The electronic component 330 can be free from being covered by a molding compound. In some embodiments, the electronic component 330 includes integrated passive device (IPD) including a capacitor, an inductor, a resistor, or a combination thereof. In some embodiments, the electronic component 330 comprises DRAM dies.

As shown in FIG. 1A, the top package 400 is stacked on the bottom package 300A by a bonding process. In some embodiments, the top package 400 includes a memory package, such as a dynamic random access memory (DRAM) package or another applicable memory package. In some embodiments, the top package 400 includes a substrate 418, at least one semiconductor dies, for example, two semiconductor dies 402 and 404 that are stacked on the substrate 418, and conductive structures 422. In some embodiments, each of the semiconductor dies 402 and 404 includes a dynamic random access memory (DRAM) die (e.g., a double data rate 4 (DDR4) DRAM die, a low-power DDR4 (LPDDR4) DRAM die, a double data rate (DDR) synchronous dynamic random access memory (SDRAM) die or the like) or another applicable memory die. In some other embodiments, the semiconductor dies 402 and 404 may include the same or different devices. In some embodiments, the top package 400 also includes one or more passive components (not illustrated), such as resistors, capacitors, inductors, the like, or a combination thereof.

In this embodiment, as shown in FIG. 1A, there are two semiconductor dies 402 and 404 mounted on the substrate 418 by a paste (not shown). The semiconductor dies 402 and 404 have corresponding pads 408 and 410 thereon, respectively. The pads 408 and 410 of the semiconductor dies 402 and 404 may be electrically connected (or coupled) to the substrate 418 using bonding wires 414 and 416, respectively. However, the number of stacked memory dies is not limited to the disclosed embodiment. Alternatively, the semiconductor dies 402 and 404 as shown in FIG. 1A can be arranged side by side and mounted on the substrate 418 by a paste (not shown).

As shown in FIG. 1A, the substrate 418 may include circuits 428 and contact pads 420 and 430 disposed in one or more extra-low K (ELK) and/or ultra-low K (ULK) dielectric layers (not shown). The contact pads 420 are disposed on the tops of the circuits 428 close to the top surface (die-attach surface) of the substrate 418. In addition, the bonding wires 414 and 416 are electrically connected (or coupled) to the corresponding contact pads 420. The contact pads 430 are disposed on the bottoms of the circuits 428 close to the bottom surface (bump-attach surface) of the substrate 418. The contact pads 430 are electrically connected (or coupled) to the corresponding contact pads 420. In some embodiments, the bonding wires 414 and 416, the contact pads 420 and 430 and the circuits 428 include a conductive material, such as metals comprising copper, gold, silver, or other applicable metals.

As shown in FIG. 1A, the conductive structures 422 are disposed on the bottom surface of substrate 418 opposite the semiconductor dies 402 and 404. For example, the conductive structures 422 may be arranged in groups along specific directions (e.g., a direction 10). The conductive structures 422 are electrically connected (or coupled) to (or in contact with) the corresponding the contact pads 430 of the substrate 418 and the first routing structure 366. In some embodiments, the conductive structures 422 include a conductive ball structure such as a copper ball, a conductive bump structure such as a copper bump or a solder bump structure, or a conductive pillar structure such as a copper pillar structure.

In some embodiments, as shown in FIG. 1A, the top package 400 further includes a molding material 412 covering the substrate 418, encapsulating the semiconductor dies 402 and 404 and the bonding wires 414 and 416. The top surface of the molding material 412 may serve as a top surface 400T of the top package 400. In some embodiments, the molding materials 312 and 412 may include the same or similar materials and fabrication processes.

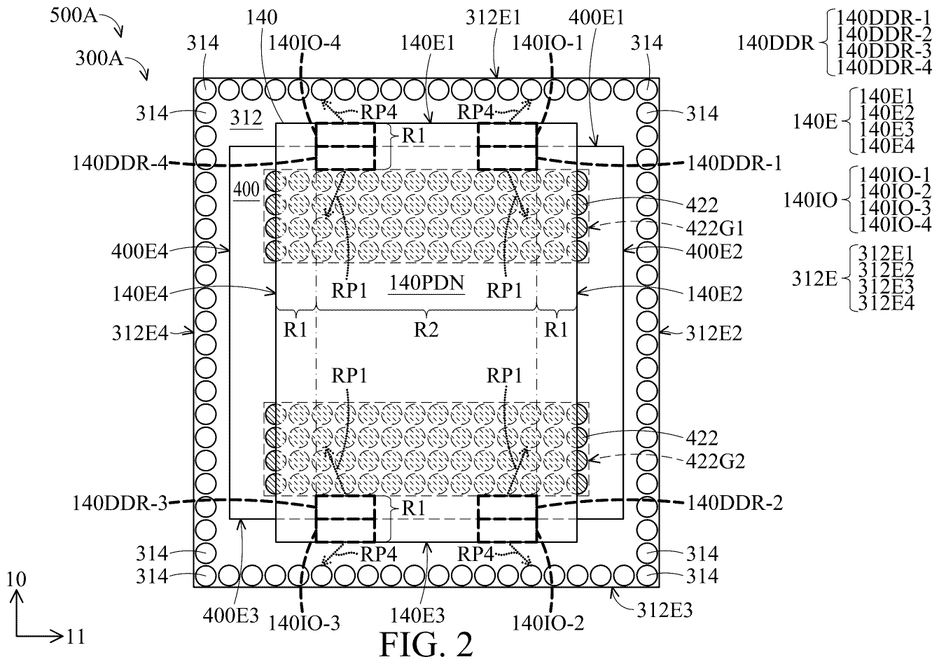

FIG. 2 is a perspective bottom view (a plan-view) of the semiconductor package assembly 500A of FIG. 1A in accordance with some embodiments of the disclosure, showing the arrangement of interfaces of the semiconductor die 140 and through via (TV) interconnects 314 of the bottom package 300A and the arrangement of conductive structures 422 of the top package 400 stacked on the bottom package 300A.

In some embodiments, the semiconductor die 140 of the bottom package 300A may be used to control the top package 400. The semiconductor die 140 may include various interfaces for external electrical connections between the bottom package 300A and the top package 400. In some embodiments, the interfaces of the semiconductor die 140 used herein may include circuitry and input/output connections (e.g. pads, the first interconnect structure 110 and the second interconnect structure 120) disposed on the first surface 140T and the second surface 140B of the semiconductor die 140. In some embodiments, the interfaces of the semiconductor die 140 are used for signal transmission (data transmission) between the bottom package 300A and the top package 400. In addition, the interfaces of the semiconductor die 140 are used for power transmission and grounding paths between the bottom package 300A and the base 200.

It is noted that FIG. 2 only shows the semiconductor die 140, the molding material 312, the TV interconnects 314 of the bottom package 300A and the conductive structures 422 of the top package 400 for illustration, the remaining features may be shown in the schematic cross-sectional views of FIGS. 1A and 1B. It is appreciated that although some features are shown in some embodiments but not in other embodiments, these features may (or may not) exist in other embodiments whenever possible. For example, although each of the illustrated example embodiments shows specific arrangements of the interfaces of the semiconductor die 140 and the TV interconnects 314 of the bottom package 300A, and the conductive structures 422 of the top package 400, any other combinations of the arrangements of the interfaces of the semiconductor die 140 and the TV interconnects 314 of the bottom package 300A, and the conductive structures 422 of the top package 400 may also be used whenever applicable.

As shown in FIG. 2, the semiconductor die 140 may have a rectangular plan-view shape. The semiconductor die 140 may have peripheral edges 140E including opposite edges 140E1 and 140E3 extending substantially along the direction 11 and opposite edges 140E2 and 140E4 substantially along the direction 10. The directions 10 and 11 may also serve as lateral directions. In some embodiments as shown in FIGS. 1A and 2, the semiconductor die 140 has a first region R1 and a second region R2. The first region R1 is located close to the peripheral edges 140E of the semiconductor die 140. The first region R1 is arranged continuous along the peripheral edges 140E. Therefore, the first region R1 is also called a peripheral edge region R1. The second region R2 is arranged corresponding to the central portion of the semiconductor die 140, also called the central region R2. The second region R2 is farther from the corresponding peripheral edge 400E than the first region R1. In addition, the first region R1 may surround the second region R2.

In some embodiments, the first region R1 may be provided for one or more I/O interfaces 140IO (e.g., interfaces 140IO-1, 140IO-2, 140IO-3 and 140IO-4) and data interfaces 140DDR (e.g., interfaces 140DDR-1, 140DDR-2, 140DDR-3, 140DDR-4) and antenna-in-package (AiP) modules (not shown) arranged within. In some embodiments, the second region R2 is provided for one or more digital intellectual property (IP) blocks (e.g., a digital IP block 140PDN (power delivery network)) disposed within.

The interfaces 140IO-1, 140IO-2, 140IO-3 and 140IO-4 may be arranged on the edges of the semiconductor die 140. For example, the interface 140IO-1 is arranged on the edge 140E1 and close to the edge 140E2. The interface 140IO-2 is arranged on the edge 140E3 and close to the edge 140E2. The interface 140IO-3 is arranged on the edge 140E3 and close to the edge 140E4. The interface 140IO-4 is arranged on the edge 140E1 and close to the edge 140E4. In some embodiments, the interfaces 140IO-1, 140IO-2, 140IO-3 and 140IO-4 are used to transmit data and digital input/output (I/O) signals to control other external ICs (not shown) connected to the base 200. In some embodiments, the edges of the semiconductor die 140 may also have interfaces for power/ground and corresponding bumps.

The interfaces 140DDR-1, 140DDR-2, 140DDR-3, 140DDR-4 may be disposed beside the interfaces 140IO-1, 140IO-2, 140IO-3 and 140IO-4. In some other embodiments, the data interfaces 140DDR may be arranged not on the edges of the semiconductor die 140. In some other embodiments, the data interfaces 140DDR may be in contact with the I/O interfaces 140IO, for example, the interface 140DDR-1 may be in contact with the interface 140IO-1, and the interface 140DDR-2 may be in contact with the interface 140IO-2. In some other embodiments, the data interfaces 140DDR may be not in contact with the I/O interfaces 140IO. For instance, the data interfaces 140DDR may be separated from the I/O interfaces 140IO, for example, the interface 140DDR-1 may be separated from the interface 140IO-1, and the interface 140DDR-2 may be separated from the interface 140IO-2. When the bottom package 300A is a SOC package, the top package 400 includes a double data rate 4 (DDR4) DRAM package, a low-power DDR4 (LPDDR4) DRAM package, a double data rate 5 (DDR5) DRAM package, a low-power DDR5 (LPDDR5) DRAM package or another applicable DRAM package. The interfaces 140DDR-1, 140DDR-2, 140DDR-3, 140DDR-4 may include double data rate 4 (DDR4) interfaces low-power DDR4 (LPDDR4) DRAM interfaces, double data rate 5 (DDR5) DRAM interfaces, low-power DDR5 (LPDDR5) DRAM interfaces or other applicable memory interfaces. The interfaces 140DDR-1, 140DDR-2, 140DDR-3, 140DDR-4 may be used for controlling the top package 400 (for example, transferring data to/from the memory controller in the semiconductor die 140).

The digital IP block 140PDN may be disposed beside the interfaces 140DDR-1, 140DDR-2, 140DDR-3, 140DDR-4. The digital IP block 140PDN is located farther from the corresponding peripheral edge 400E than the interfaces 140DDR-1, 140DDR-2, 140DDR-3, 140DDR-4 and the interfaces 140IO-1, 140IO-2, 140IO-3 and 140IO-4. The digital IP block 140PDN may provide a power distribution network to ensure stable power delivery to all electronic components of the semiconductor die 140.

In some embodiments, the conductive structures 422 of the top package 400 (e.g. the DDR4 DRAM package) are arranged according the given arrangement. For example, the conductive structures 422 of the top package 400 are arranged in two groups 422G1 and 422G2 (including a single column or multi-columns of the conductive structures 422) on the opposite edges 400E1 and 400E3 of the top package 400 along the direction 11, as shown in FIG. 2. Each of the group 422G1 and 422G2 of conductive structures 422 may provide two data channels for the conductive structures 422. That is, the group 422G1 provides two DDR channels (DDR interface of semiconductor die 140 to the top package 400), and the group 422G2 provides two DDR channels. In some other embodiments, the top package 400 may further include additional conductive structures 422 (including a single column or multi-columns of the conductive structures 422) arranged on the edges 400E2 and 400E4 of the top package 400 for power transmission and grounding. In addition, the additional conductive structures 422 may be arranged according to the standards for the data rates of DDR. In some other embodiments, the distribution region of the conductive structures 422 (including the additional conductive structures 422) may have a hollow square shape.

Since the semiconductor die 140 of the bottom package 300A is used in back-side power technology, the semiconductor die 140 may have a first interconnect structure 110 and a second interconnect structure 120 on opposite surfaces (e.g., the front surface 100F and the back surface 100B) of the semiconductor substrate 100. The data channel of the semiconductor dies 402 and 404 of the top package 400 may be electrically connected (or coupled) to the data interfaces 140DDR (including the interfaces 140DDR-1, 140DDR-2, 140DDR-3 and 140DDR-4) of the semiconductor die 140 by a routing path RP1 composed of the conductive structures 422, the first routing structure 366, the conductive bumps 114 and the first interconnect structure 110 (including the signal routings 112S). The semiconductor dies 402 and 404 may be electrically connected (or coupled) to the data interfaces 140DDR (including the interfaces 140DDR-1, 140DDR-2, 140DDR-3 and 140DDR-4) of the semiconductor die 140 without using the TV interconnects 314 and the second routing structure 316. More TV interconnects 314 originally provided as the electrical connections between the data interfaces 140DDR and the top package 400 may be released for the electrical connections between the I/O interfaces 140IO (including the interfaces 140IO-1, 140IO-2, 140IO-3 and 140IO-4) and the base 200, or between the top package 400 and the base 200. In addition, the data interfaces 140DDR may be arranged to be farther from the corresponding edges 140E of the semiconductor die 140 than the I/O interfaces 140IO. The routing path RP1 for transmitting signal between the data interfaces 140DDR of the bottom package 300A and the data channel of the top package 400 may be a reduced length. Since the TV interconnects 314 are no longer to provide as the electrical connections between the data interfaces 140DDR and the top package 400, the conductive structures 422 may provide more DDR channels between the data interfaces 140DDR of the semiconductor die 140 and the top package 400 in a condition that the bottom package 300A maintains the same size. Furthermore, the area on the edges 140E1 to 140E4 of the semiconductor die 140 originally occupied by the data interfaces 140DDR may be released to make room for more I/O interfaces. Moreover, the floorplan design of digital IP block 140PDN is not suffered from the arrangement of the I/O interfaces 140IO. The performance of the semiconductor package assembly 500A can be improved with maintaining power integrity.

Moreover, the data interfaces 140DDR (including the interfaces 140DDR-1, 140DDR-2, 140DDR-3 and 140DDR-4) of the bottom package 300A may be electrically connected to the base 200 by a routing path RP2 composed of the second interconnect structure 120, the conductive bumps 124, the second routing structure 316 and the conductive structures 322 for power transmission and grounding paths. The data interfaces 140DDR of the semiconductor die 140 may be electrically connected (or coupled) to the base 200 without using the TV interconnects 314. In the current design, the semiconductor die of the bottom package is flipped, with the active surface of the semiconductor die facing down, and the DDR interfaces of the semiconductor die are set at the edge of the semiconductor die. As a result, the DDR channels between the DDR interface of the semiconductor die and the top package can only be realized through the second routing structure 316, the TV interconnects 314 (and the first routing structure 366, etc.). These DDR channels will occupy a considerable amount of the second routing structure 316 and the TV interconnects 314. Therefore, due to the DDR routing constraints, some conductive structures 322 cannot be used (e.g., cannot be used to transmit power or signals due to routing requirements), necessitating the addition of extra conductive structures 322, thereby increasing the size of the bottom package 300. In an embodiment of the present disclosure, the semiconductor die 140 of the bottom package 300 is not flipped (the active surface of the semiconductor die 140 is face up), and a connection structure (such as the first interconnect structure 110 and the conductive bumps 114) is set on the first surface (front surface or active surface) 140T of the semiconductor die 140, with the DDR interfaces not set at the edge of the semiconductor die. This allows the DDR channels to avoid occupying the second routing structure 316 and the TV interconnects 314, and directly communicate with the top package 400 through the first interconnect structure 110 and the conductive bumps 114. Therefore, the solution of the embodiment of the present disclosure can release the second routing structure 316 and the TV interconnects 314 for other uses, and also reserve the valuable edge position of the semiconductor die for other interfaces. This setting not only shortens the circuit path with DDR but also frees up the valuable die edge resources, thereby improving the flexibility of the design. In addition, since the number of the conductive structures 322 that cannot be used is reduced, the size of the bottom package 300 will also be reduced.

In addition, the semiconductor dies 402 and 404 of the top package 400 may be electrically connected (or coupled) to the base 200 by a routing path RP3 composed of the conductive structures 422, the first routing structure 366, the TV interconnects 314, the second routing structure 316 and the conductive structures 322 for power transmission and grounding. Therefore, the TV interconnects 314 electrically connected between the top package 400 and the base 200 may serve as power TV interconnects, ground TV interconnects, or a combination thereof.

Since the semiconductor die 140 of the bottom package 300A is used in back-side power technology, the I/O interfaces 140IO (including the interfaces 140IO-1, 140IO-2, 140IO-3 and 140IO-4) of the bottom package 300A may have various routing paths for signal transmission, power transmission and grounding. For example, the I/O interfaces 140IO (including the interfaces 140IO-1, 140IO-2, 140IO-3 and 140IO-4) of the bottom package 300A may be electrically connected (or coupled) to the external ICs (not shown) connected to the base 200 by a routing path RP4 composed of the first interconnect structure 110, the conductive bumps 114, the first routing structure 366, the TV interconnects 314, the second routing structure 316 and the conductive structures 322. Therefore, the TV interconnects 314 electrically connected (or coupled) between the I/O interfaces 140IO (including the interfaces 140IO-1, 140IO-2, 140IO-3 and 140IO-4) and the base 200 may serve as signal TV interconnects, power TV interconnects, ground TV interconnects, or a combination thereof. Alternatively, the I/O interfaces 140IO (including the interfaces 140IO-1, 140IO-2, 140IO-3 and 140IO-4) of the bottom package 300A may be electrically connected (or coupled) to the external ICs (not shown) connected to the base 200 by a routing path RP5 composed of the second interconnect structure 120, the conductive bumps 124, the second routing structure 316 and the conductive structures 322.

Furthermore, the digital IP block 140PDN may be electrically connected (or coupled) to the base 200 by a routing path RP6 composed of the second interconnect structure 120, the conductive bumps 124, the second routing structure 316 and the conductive structures 322 for power transmission.

In some embodiments, the conductive bumps 114 may be disposed only on the data interfaces 140DDR (including the interfaces 140DDR-1, 140DDR-2, 140DDR-3 and 140DDR-4) and the I/O interfaces 140IO (including the interfaces 140IO-1, 140IO-2, 140IO-3 and 140IO-4) but not on the digital IP block 140PDN. In some embodiments, the conductive bumps 124 may be disposed on the data interfaces 140DDR, the I/O interfaces 140IO and the digital IP block 140PDN.

Since the TV interconnects 314 may be used as electrical connections for the semiconductor dies 402 and 404 of the top package 400 and the I/O interfaces 140IO (including the interfaces 140IO-1, 140IO-2, 140IO-3 and 140IO-4) of the bottom package 300A, the TV interconnects 314 may be arranged corresponding to the conductive structures 422 and the I/O interfaces 140IO (including the interfaces 140IO-1, 140IO-2, 140IO-3 and 140IO-4) of the bottom package 300A. For example, the TV interconnects 314 may be arranged in single column or multi-columns on edges 312E (including edges 312E1, 312E2. 312E3 and 312E4) of the molding compound 312 corresponding to the conductive structures 422 and the I/O interfaces 140IO (including the interfaces 140IO-1, 140IO-2, 140IO-3 and 140IO-4) of the bottom package 300A. The distribution region of the TV interconnects 314 may have a hollow square shape, as shown in FIG. 2. In some embodiments, the I/O interfaces 140IO can be electrically connected (or coupled) to the conductive structures 322 through the conductive bumps 114, the first routing structure 366, and the TV interconnects 314. In some embodiments, the I/O interfaces 140IO may not transmit signals to the conductive structures 422. In some embodiments, when the interface on the first surface 140T of the semiconductor die 140 is a DDR interface, the conductive bumps 124 on the second surface 140B of the semiconductor die 140 corresponding to the DDR interface may be power bumps for supplying power to the DDR circuit. In some embodiments, when the interface on the first surface 140T of the semiconductor die 140 is a I/O interface, the conductive bumps 124 on the second surface 140B of the semiconductor die 140 corresponding to the I/O interface may be power bumps for supplying power to the I/O circuit. In some embodiments, some circuits of the semiconductor die 140 can also be connected (or coupled) to the base 200 through the conductive bumps 114 on the first surface 140T of the semiconductor die 140, the first routing structure 366, the TV interconnects 314, and the second routing structure 316 to transmit signals.

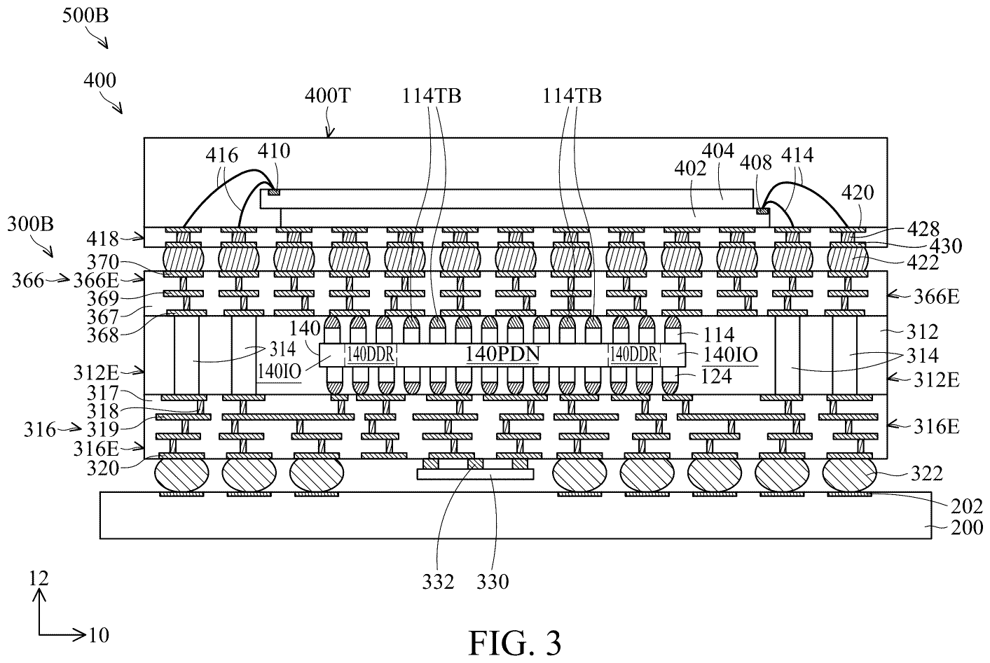

FIG. 3 is a cross-sectional view of a semiconductor package 500B assembly in accordance with some embodiments of the disclosure. Elements of the embodiments hereinafter, that are the same or similar as those previously described with reference to FIGS. 1A, 1B and 2, are not repeated for brevity. As shown in FIGS. 1 to 3, the difference between the semiconductor package assembly 500A and the semiconductor package assembly 500B at least includes that the semiconductor die 140 of a bottom package 300B of the semiconductor package assembly 500B may include conductive bumps 114TB as thermal bumps to dissipate heat generated form the semiconductor die 140.

As shown in FIG. 3, the conductive bumps 114TB are disposed on the first surface 140T (as shown in FIG. 1B) of the semiconductor die 140. Because the digital IP block 140PDN is electrically connected (or coupled) to the base 200 without using the conductive bumps on the front surface 100F (as shown in FIG. 1B) of the semiconductor substrate 100, the conductive bumps 114TB may be disposed directly on the digital IP block 140PDN in the central region R2 of the semiconductor die 140. In addition, the conductive bumps 114TB may be offset from (separated from) the data interfaces 140DDR (including the interfaces 140DDR-1, 140DDR-2, 140DDR-3 and 140DDR-4) and the I/O interfaces 140IO (including the interfaces 140IO-1, 140IO-2, 140IO-3 and 140IO-4) in the direction 10 (or the direction 11 as shown in FIG. 2). The conductive bumps 114TB are in contact the first routing structure 366 and the first interconnect structure 110. In some embodiments, the conductive bumps 114TB are grounded. In some embodiments, the conductive bumps 114TB and the conductive bumps 114 may be the same size or difference sizes. For example, the size of the conductive bumps 114TB may be the same or similar to the size of the conductive bumps 114. Alternatively, the size of the conductive bumps 114TB may be greater than the size of the conductive bumps 114 to further improve heat dissipation efficiency. Since the conductive bumps 114TB have the thermal resistance lower than the molding compound 312, the arrangement of the conductive bumps 114TB may help to dissipate heat generated form the semiconductor die 140, heat dissipation efficiency from the semiconductor die 140 to the environment outside the semiconductor package 500B can be improved.

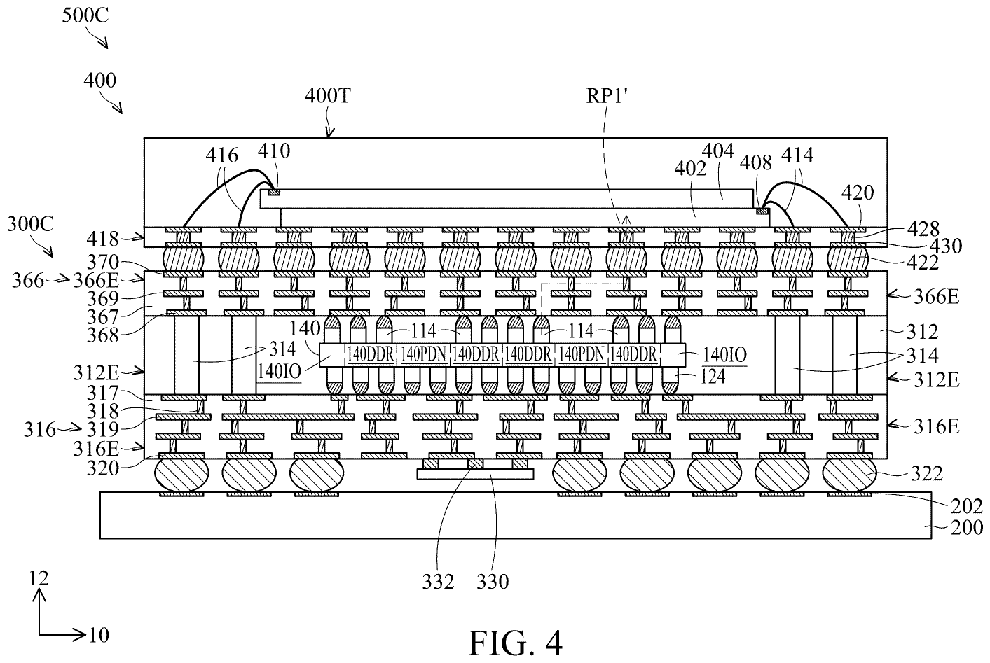

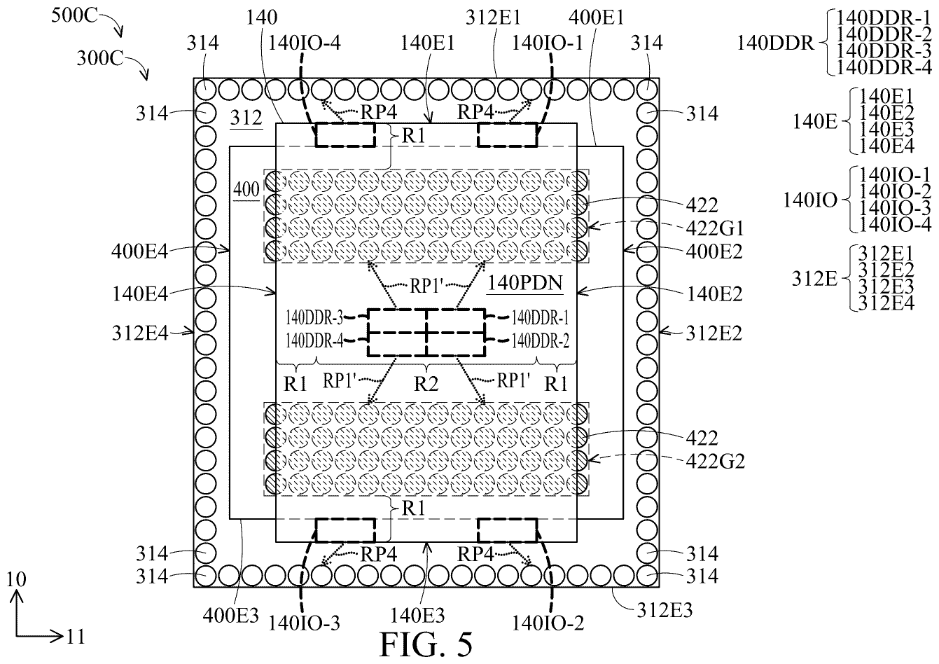

FIG. 4 is a cross-sectional view of a semiconductor package 500C assembly in accordance with some embodiments of the disclosure. FIG. 5 is a perspective bottom view of the semiconductor package assembly 500C of FIG. 4 in accordance with some embodiments of the disclosure, showing the arrangement of interfaces of the semiconductor die 140 and through via (TV) interconnects 314 of a bottom package 300C and the arrangement of conductive structures 422 of the top package 400 stacked on the bottom package 300C. Elements of the embodiments hereinafter, that are the same or similar as those previously described with reference to FIGS. 1A, 1B and 2, are not repeated for brevity. As shown in FIGS. 1A and 2, the difference between the semiconductor package assembly 500A and the semiconductor package assembly 500C at least includes that the data interfaces 140DDR (including the interfaces 140DDR-1, 140DDR-2, 140DDR-3 and 140DDR-4) of the bottom package 300C of the semiconductor package assembly 500C are arranged in the central region R2 of the semiconductor die 140. This embodiment can further shorten the path length of the DDR channel from the top package 400 (or the semiconductor dies 402 and 404) to the semiconductor die 140 (e.g., the internal circuit of the semiconductor die 140), thereby further reducing latency.

In this embodiment, the interfaces 140DDR-1, 140DDR-2, 140DDR-3, 140DDR-4 are arranged adjacent to one another. The interfaces 140DDR-1, 140DDR-2, 140DDR-3, 140DDR-4 are located between the groups 422G1 and 422G2 of the conductive bumps 422 in a plan-view as shown in FIG. 5. In some embodiments, the multiple data interfaces 140DDR may be adjacent to each other to form an array that contains only DDR interfaces and no other types of interfaces. This arrangement allows the position of the DDR interface array to be aligned with other circuit blocks (such as digital circuit blocks) without being affected by the DDR channel, thereby avoiding the waste of die area.

In this embodiment, the digital IP block 140PDN may surround the data interfaces 140DDR (including the interfaces 140DDR-1, 140DDR-2, 140DDR-3 and 140DDR-4).

In some embodiments, the conductive bumps 114 electrically connected (or coupled) to the data interfaces 140DDR (including the interfaces 140DDR-1, 140DDR-2, 140DDR-3 and 140DDR-4) may be arranged in the central region R2 of the semiconductor die 140.

According to the arrangement of the data interfaces 140DDR (including the interfaces 140DDR-1, 140DDR-2, 140DDR-3 and 140DDR-4), a routing path RP1′ for transmitting signal between the data interfaces 140DDR (including the interfaces 140DDR-1, 140DDR-2, 140DDR-3 and 140DDR-4) of the bottom package 300C and the data channel of the top package 400 may be shorter than the routing path RP1 as shown in FIG. 1. The semiconductor package assembly 500C may have improved computing performance.

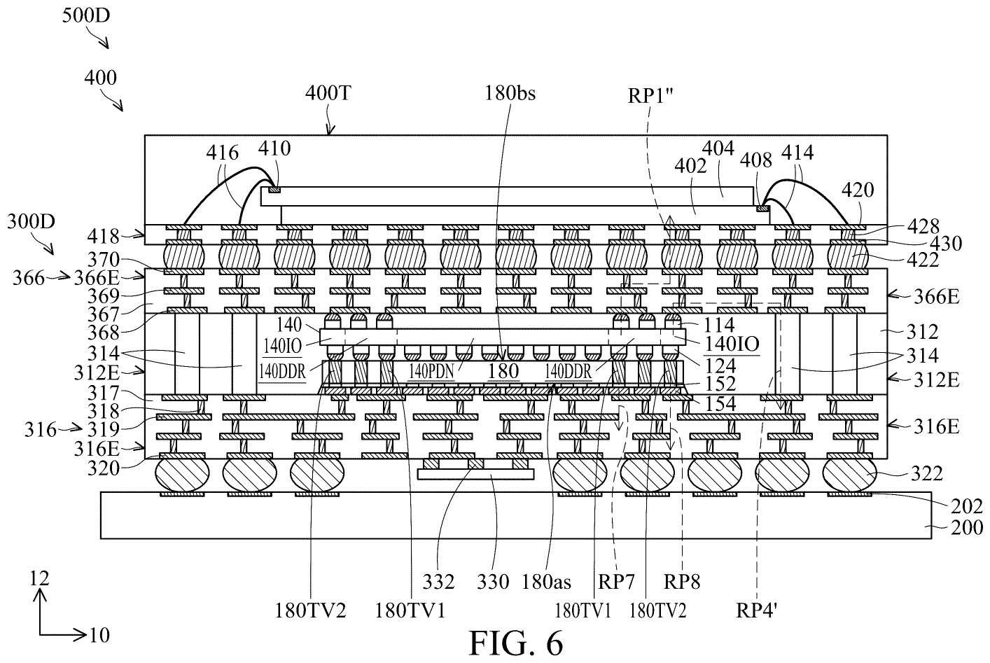

FIG. 6 is a cross-sectional view of a semiconductor package assembly 500D in accordance with some embodiments of the disclosure. Elements of the embodiments hereinafter, that are the same or similar as those previously described with reference to FIGS. 1A, 1B, 2 to 5, are not repeated for brevity. As shown in FIG. 1A, the difference between the semiconductor package assembly 500A and the semiconductor package assembly 500D at least includes that a bottom package 300D of the semiconductor package assembly 500D further includes a semiconductor die 180.

In some embodiments, the semiconductor package assembly 500D is a three-dimensional (3D) chiplet package assembly. In some embodiments, the bottom package 300D uses a chiplet architecture to split a large, single semiconductor die into multiple smaller functional semiconductor dies (called chiplets) fabricated in different technology nodes. Each chiplet may have improved device performance and fabrication yields. In addition, the bottom package 300D may have a reduced fabrication cost. As shown in FIG. 6, the bottom package 300D includes at least two semiconductor dies, for example, the semiconductor dies 140 and 180 (also called chiplets 140 and 180) stacked on each other along the direction 12 (e.g., a vertical direction). The semiconductor die 180 is disposed between the semiconductor die 140 and the second routing structure 316. The semiconductor die 180 may be surrounded by the TV interconnects 314. The semiconductor die 180 may overlap the semiconductor die 140 and the top package 400 along the direction 12. Since the semiconductor die 140 and the semiconductor die 180 are respectively close to the first routing structure 366 and the second routing structure 316 of the bottom package 300D, the semiconductor die 140 and the semiconductor die 180 may be also called a top semiconductor die 140 and a bottom semiconductor die 180.

In some embodiments, the semiconductor die 180 includes a system-on-chip (SoC) die, a logic device, a memory device, a radio frequency (RF) device, the like, or any combination thereof. For example, the semiconductor die 140 and the semiconductor die 180 may each independently include a micro control unit (MCU) die, a microprocessor unit (MPU) die, a power management integrated circuit (PMIC) die, a global positioning system (GPS) device, a central processing unit (CPU) die, a graphics processing unit (GPU) die, an input-output (IO) die, a dynamic random access memory (DRAM) IP core, a static random-access memory (SRAM), a high bandwidth memory (HBM), the like, or any combination thereof. In some embodiments, the semiconductor die 140 and the semiconductor die 180 have different functions.

The semiconductor dies 140 and 180 may be fabricated in different technology nodes. In some embodiments, the semiconductor die 140 has a first critical dimension (CD) and the semiconductor die 180 has a second critical dimension different from the first critical dimension in order to provide different functionalities with a reduced cost. For example, the first critical dimension is narrower than the second critical dimension. Therefore, the semiconductor dies 140 and 180 may respectively arrange various interfaces to fulfill the requirements of internal and external signal transmission of the bottom package 300D.

In some embodiments, the semiconductor die 180 is fabricated by a flip-chip technology. The semiconductor die 180 may be flipped to be disposed on the second routing structure 316 opposite the conductive structures 322. In addition, the second routing structure 316 is disposed between the semiconductor die 180 and the base 200 along the direction 12.

The semiconductor die 180 has an active surface 180a and a backside surface 180b opposite to the active surface 180a. Pads 152 on the active surface 132 as of the semiconductor die 180 are electrically connected (or coupled) to the second routing structure 316 using conductive structures 154. In some embodiments, the conductive structures 154 include conductive materials, such as metal. The conductive structures 154 may include microbumps, controlled collapse chip connection (C4) bumps, ball grid array (BGA) balls, the like, or a combination thereof.

In some embodiments, the semiconductor die 180 further includes through via (TV) interconnects 180TV1 formed passing through the semiconductor die 180. Therefore, the semiconductor die 180 may be also called a TV die 180. The TV interconnects 180TV1 may be exposed form the backside surface 180bs of the semiconductor die 180. In addition, the TV interconnects 180TV1 have substantially vertical sidewalls and extend from the active surface 180as and the backside surface 180bs of the semiconductor die 180, but the present disclosure is not limit thereto. The TV interconnects 180TV1 in the semiconductor die 180 may have other configurations and numbers. In some embodiments, the TV interconnects 180TV1 may be formed of conductive material, such as a metal. For example, the TV interconnects 180TV1 may be formed of copper.

In some embodiments, the TV interconnects 180TV1 of the semiconductor die 180 may overlap and electrically connected (or coupled) to the data interfaces 140DDR (including the interfaces 140DDR-1, 140DDR-2, 140DDR-3 and 140DDR-4) of the semiconductor die 140. The second routing structure 316 is electrically connected (or coupled) to the data interfaces 140DDR of the semiconductor die 140 by the conductive bumps 124 and the semiconductor die 180. In some embodiments, the data interfaces 140DDR of the bottom package 300D may be electrically connected (or coupled) to the base 200 by a routing path RP7 composed of the second interconnect structure 120, the conductive bumps 124, the second routing structure 316, the TV interconnects 180TV1, the pads 152, the conductive structures 154, the second routing structure 316 and the conductive structures 322 for power transmission and grounding paths. Therefore, the TV interconnects 180TV1 electrically connected (or coupled) to the data interfaces 140DDR of the semiconductor die 140 may serve as power TV interconnects, ground TV interconnects, or a combination thereof. The data interfaces 140DDR of the semiconductor die 140 may be electrically connected (or coupled) to the base 200 without using the TV interconnects 314. The number of the TV interconnects 314 can be further reduced.

Since the semiconductor die 140 of the bottom package 300D is used in back-side power technology, the interfaces 140DDR-1, 140DDR-2, 140DDR-3 and 140DDR-4 of the bottom package 300D may be electrically connected (or coupled) to the data channel of the top package 400 by a routing path RP1″ (similar to the routing path RP1 as shown in FIG. 1) without using the TV interconnects formed passing through the semiconductor die 180 for signal transmission (data transmission). The TV interconnects formed passing through the semiconductor die 180 of the semiconductor package assembly 500D may have a reduced number than the conventional three-dimensional (3D) chiplet package assembly.

Since the semiconductor die 140 of the bottom package 300D is used in back-side power technology, the I/O interfaces 140IO (including the interfaces 140IO-1, 140IO-2, 140IO-3 and 140IO-4) of the bottom package 300D may have various routing paths for signal transmission, power transmission and grounding. In some embodiments, the semiconductor die 180 further includes through via (TV) interconnects 180TV2 formed passing through the semiconductor die 180. The TV interconnects 180TV2 of the semiconductor die 180 may overlap and electrically connected (or coupled) to the I/O interfaces 140IO (including the interfaces 140IO-1, 140IO-2, 140IO-3 and 140IO-4) of the semiconductor die 140. The second routing structure 316 is electrically connected (or coupled) to the I/O interfaces 140IO of the semiconductor die 140 by the conductive bumps 124 and the semiconductor die 180. In some embodiments, the I/O interfaces 140IO of the bottom package 300D may be electrically connected (or coupled) to the base 200 by a routing path RP8 composed of the second interconnect structure 120, the conductive bumps 124, the TV interconnects 180TV1, the pads 152, the conductive structures 154, the second routing structure 316 and the conductive structures 322 for power transmission and grounding paths. Therefore, the TV interconnects 180TV2 electrically connected (or coupled) to the interfaces I/O interfaces 140IO of the semiconductor die 140 may serve as signal TV interconnects, power TV interconnects, ground TV interconnects, or a combination thereof. The I/O interfaces 140IO of the semiconductor die 140 may be electrically connected (or coupled) to the external ICs (not shown) connected to the base 200 without using the TV interconnects 314. The number of the TV interconnects 314 can be further reduced. In addition, the size of the semiconductor die 180 can be further reduced.

In some other embodiments, the I/O interfaces 140IO (including the interfaces 140IO-1, 140IO-2, 140IO-3 and 140IO-4) of the semiconductor die 140 may be electrically connected (or coupled) to the external ICs (not shown) connected to the base 200 by a routing path RP4′ composed of the first interconnect structure 110, the conductive bumps 114, the first routing structure 366, the TV interconnects 314, the second routing structure 316 and the conductive structure, which is similar to the routing path RP4 as shown in FIG. 1.

As shown in FIG. 6, the bottom package 300D may further include underfills (not shown) filling a gap (not shown) between the second routing structure 316 and the semiconductor die 180. In some embodiments, the underfills surround portions of the conductive structures 154 and are in contact with portions of the second routing structure 316 to further reduce the thermal resistance from the semiconductor die 180 to the second routing structure 316. In addition, the underfills may be disposed to compensate for differing coefficients of thermal expansion (CTEs) between the semiconductor die 180, the second routing structure 316 and the conductive structures 154. In some embodiments, the underfill includes a capillary underfill (CUF), a molded underfill (MUF), or a combination thereof.

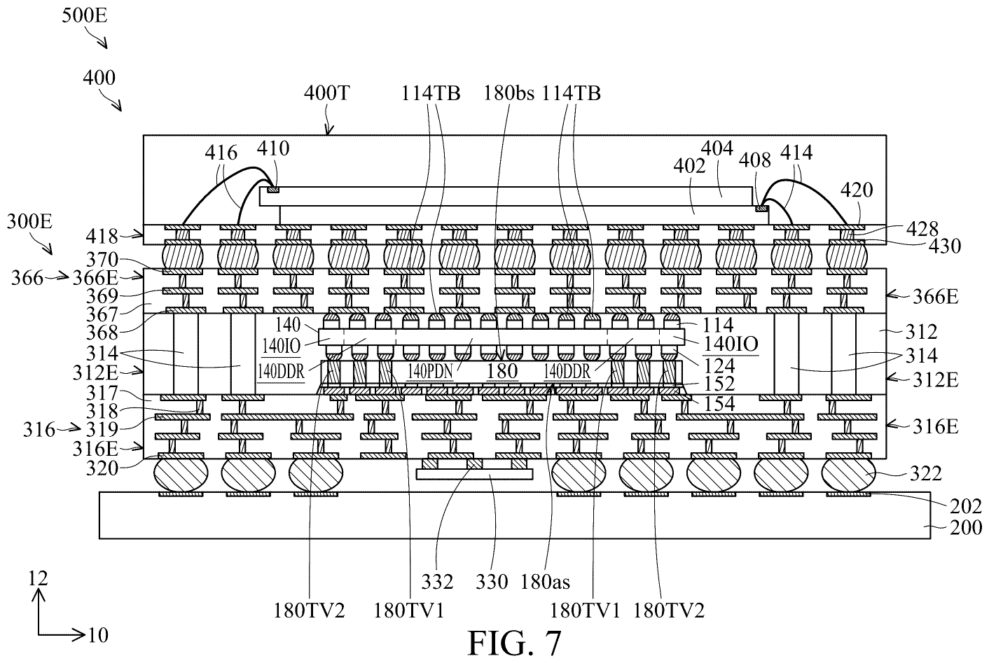

FIG. 7 is a cross-sectional view of a semiconductor package assembly 500E in accordance with some embodiments of the disclosure. Elements of the embodiments hereinafter, that are the same or similar as those previously described with reference to FIGS. 1A, 1B, 2 to 6, are not repeated for brevity. As shown in FIGS. 6 and 7, the difference between the semiconductor package assembly 500D and the semiconductor package assembly 500E at least includes that that the semiconductor die 140 of a bottom package 300E of the semiconductor package assembly 500E may include the conductive bumps 114TB as thermal bumps to dissipate heat generated form the semiconductor die 140. In some embodiments, the arrangement of the conductive bumps 114TB of the semiconductor package assembly 500E may be the same or similar to the conductive bumps 114TB of the semiconductor package assembly 500B.

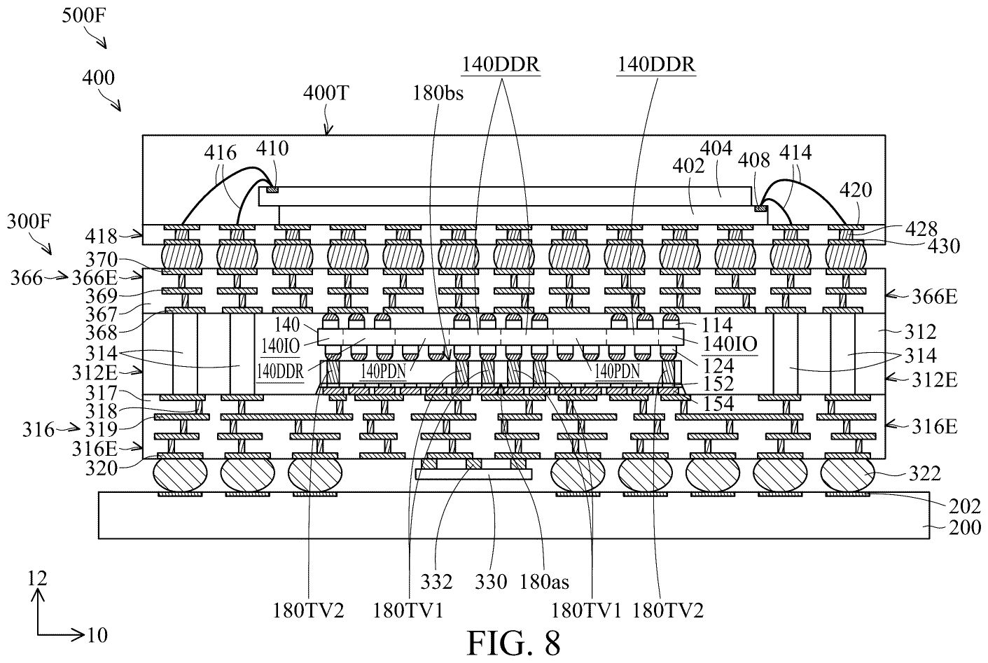

FIG. 8 is a cross-sectional view of a semiconductor package assembly 500F in accordance with some embodiments of the disclosure. Elements of the embodiments hereinafter, that are the same or similar as those previously described with reference to FIGS. 1A, 1B, 2 to 7, are not repeated for brevity. As shown in FIGS. 6 and 8, the difference between the semiconductor package assembly 500E and the semiconductor package assembly 500F at least includes that the data interfaces 140DDR (including the interfaces 140DDR-1, 140DDR-2, 140DDR-3 and 140DDR-4) of a bottom package 300F of the semiconductor package assembly 500C are arranged in the central region R2 of the semiconductor die 140. In some embodiments, the arrangement of the data interfaces 140DDR (including the interfaces 140DDR-1, 140DDR-2, 140DDR-3 and 140DDR-4) of the semiconductor package assembly 500F may be the same or similar to the data interfaces 140DDR (including the interfaces 140DDR-1, 140DDR-2, 140DDR-3 and 140DDR-4) of the semiconductor package assembly 500C. In addition, the TV interconnects 180TV1 corresponding to the data interfaces 140DDR (including the interfaces 140DDR-1, 140DDR-2, 140DDR-3 and 140DDR-4) may be arranged in the central region R2 of the semiconductor die 140. The semiconductor package assembly 500F may have advantages the same or similar to those of the semiconductor package assembly 500C.

Embodiments provide a semiconductor package assembly, the semiconductor package assembly includes a bottom package (e.g., a SOC package) and a top package (e.g., a memory package) stacked on the bottom package. The bottom package includes at least one semiconductor die (e.g., a logic die) applied in back-side power technology. More TV interconnects (e.g., the TV interconnect 314) surrounding the semiconductor die and originally provided as the electrical connections between the DDR interfaces (e.g., the interfaces 140DDR-1, 140DDR-2, 140DDR-3 and 140DDR-4) and the top package may be released for the electrical connections between the I/O interfaces (e.g., the interfaces 140IO-1, 140IO-2, 140IO-3 and 140IO-4) and the base, or between the top package and the base.

In addition, the DDR interfaces may be placed farther from the corresponding edges of the semiconductor die than the I/O interfaces (e.g., the DDR interfaces may be arranged in the central region of the semiconductor die). The routing path (e.g., the routing path RP1) for transmitting signal between the DDR interfaces of the bottom package and the data channel of the top package may be a reduced length. More conductive structures (e.g., conductive structures 422) of the top package can be arranged without being constrained by the location of the TV interconnects of the bottom package. The increased conductive structures may be provided for signal transmission (data transmission) between the bottom package and the top package. In addition, the increased conductive structures may be provided for power transmission and grounding paths between the top package and the base. Furthermore, the area on the edges of the semiconductor die of the bottom package originally occupied by the DDR interfaces may be released to make room for more I/O interfaces. The performance of the semiconductor package assembly can be improved.

Moreover, the TV interconnects surrounding the semiconductor die may be used as electrical connections for the top package and the I/O interfaces of the bottom package. The distribution region of the TV interconnects may have a hollow square shape corresponding to the conductive structures of the top package and the I/O interfaces of the bottom package.

In some embodiments, the bottom package of the semiconductor package assembly may include grounded conductive bumps disposed directly on the digital IP block (e.g., the digital IP block 140PDN) in the central region of the semiconductor die. The grounded conductive bumps may help to improve heat dissipation efficiency from the semiconductor die 140 to the environment outside the semiconductor package assembly.

In some embodiments, the bottom package of the semiconductor package assembly includes two semiconductor dies (e.g., logic dies) fabricated with different critical dimensions. The top semiconductor die having a narrower critical dimension is used to control the top package and includes interfaces for external electrical connections between the bottom package and the top package, or between the bottom package and the base. The bottom semiconductor die fabricated with a wider critical dimension may include TV interconnects (e.g., the TV interconnect 180TV1) for power transmission and grounding paths of the DDR interfaces of the first semiconductor die. Since the top semiconductor die is used in back-side power technology, the TV interconnects passing through the bottom semiconductor die are not used for DDR signal transmission and have a reduced number. The size of the bottom semiconductor die can be further reduced.

Embodiments provide a semiconductor package assembly, the semiconductor package assembly includes a first semiconductor die and a second semiconductor die. The first semiconductor die has a first surface and a second surface opposite the first surface. The first semiconductor die includes a first conductive bump, a second conductive bump, a first interface and a second interface. The first conductive bump is disposed on the first surface of the first semiconductor die. The second conductive bump is disposed on the second surface of the first semiconductor die. The first interface is arranged on a first edge of the first semiconductor die. The second interface is arranged beside the first interface. The second interface is farther from the corresponding first edge of the first semiconductor die than the first interface. The second semiconductor die is stacked on the first semiconductor die. The second semiconductor die is electrically coupled to the first semiconductor die by the second interface.

In some embodiments, the first semiconductor die further includes a semiconductor substrate, a first interconnect structure and a second interconnect structure disposed on opposite surfaces of the semiconductor substrate. The first conductive bump is separated from the second conductive bump by the semiconductor substrate, the first interconnect structure and the second interconnect structure.

In some embodiments, the semiconductor package assembly further includes a first routing structure in contact with the first conductive bump. The second semiconductor die is electrically coupled to the second interface of the first semiconductor die by the first conductive bump and the first routing structure.

In some embodiments, the first routing structure is disposed between the first semiconductor die and the second semiconductor die.

In some embodiments, the first semiconductor die further includes a third conductive bump disposed on the first surface of the first semiconductor die and in contact with the first routing structure. The third conductive bump is grounded.

In some embodiments, the third conductive bump is located in a central region of the first semiconductor die.

In some embodiments, the semiconductor package assembly further includes a second routing structure, a first through via (TV) interconnect and a second through via (TV) interconnect. The second routing structure is disposed below the second conductive bump. The first through via (TV) interconnect and a second through via (TV) interconnect are disposed beside the first semiconductor die and electrically coupled between the first routing structure and the second routing structure. The second routing structure is electrically coupled to the first interface of the first semiconductor die by the first TV interconnect and the first routing structure.

In some embodiments, the second routing structure is in contact with the second conductive bump.

In some embodiments, the second routing structure is electrically coupled to the first interface of the first semiconductor die by the second conductive bump.

In some embodiments, the semiconductor package assembly further includes a second through via (TV) interconnect. The second through via (TV) interconnect is disposed beside the first semiconductor die and electrically coupled between the first routing structure and the second routing structure. The second semiconductor die is electrically coupled to the second routing structure by the first routing structure and the second TV interconnect. In some embodiments, the second TV interconnect is a power TV interconnect.

In some embodiments, the semiconductor package assembly further includes a molding compound. The molding compound surrounds the first semiconductor die, wherein the first TV interconnect and the second TV interconnect pass through the molding compound.

In some embodiments, the first conductive bump is a signal bump, and the second conductive bump is a power bump.

In some embodiments, the semiconductor package assembly further includes a fan-out package and a memory package. The fan-out package includes the first semiconductor die, the first routing structure and the second routing structure. The memory package includes the third semiconductor die and stacked on the fan-out package. The memory package includes third conductive bumps arranged in groups and disposed on opposite edge of the memory package.

In some embodiments, the second interface is located between the groups of third conductive bumps in a plan-view.

In some embodiments, the second interface is located in a central region of the first semiconductor die.

In some embodiments, the semiconductor package assembly further includes a fourth semiconductor die. The fourth semiconductor die is disposed between the first semiconductor die and the second routing structure. The second routing structure is electrically coupled to the first interface of the first semiconductor die by the second conductive bump and the fourth semiconductor die.

In some embodiments, the fourth semiconductor die further includes a third through via (TV) interconnect. The third through via (TV) interconnect is formed passing through the fourth semiconductor die. The third TV interconnect overlaps the second interface. The third TV interconnect is electrically coupled to the second interface.

In some embodiments, the third TV interconnect is a power TV interconnect or a ground TV interconnect.

In some embodiments, thee fourth semiconductor die further includes a fourth through via (TV) interconnect. The fourth through via (TV) interconnect is formed passing through the fourth semiconductor die, wherein the fourth TV interconnect overlaps the first interface. The fourth TV interconnect is electrically coupled to the first interface.

Embodiments provide a semiconductor package assembly, the semiconductor package assembly includes a base, a fan-out package and a memory package. The fan-out package is mounted on the base. The fan-out package includes a first routing structure, a second routing structure and a top semiconductor die. The first routing structure and the second routing structure are stacked on each other. The top semiconductor die is disposed between the first routing structure and the second routing structure. The top semiconductor die includes a first interface and a second interface. The first interface is arranged on a first edge of the top semiconductor die. The second interface is arranged adjacent to the first interface. The second interface is farther from the corresponding first edge of the top semiconductor die than the first interface. The memory package is disposed on the fan-out package. The base is electrically coupled to the first interface by at least the first routing structure. The memory package is electrically coupled to the second interface by the first routing structure rather than the second routing structure.

In some embodiments, the base is electrically coupled to the second interface by the second routing structure rather than the first routing structure.

In some embodiments, the top semiconductor die further includes a conductive bump. The conductive bump is disposed offset from the second interface and in contact with the first routing structure. The conductive bump is grounded.

In some embodiments, the fan-out package further includes a bottom semiconductor die. The bottom semiconductor die is disposed between the top semiconductor die and the second routing structure. The bottom semiconductor die includes a through via (TV) interconnect overlapping and electrically coupled to the second interface.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor package assembly, comprising:
a first semiconductor die having a first surface and a second surface opposite to the first surface, wherein the first semiconductor die comprises:
a first interface arranged on a first edge of the first semiconductor die; and
a second interface beside the first interface, wherein the second interface is farther from the first edge of the first semiconductor die than the first interface; and
a second semiconductor die stacked on the first semiconductor die;
wherein the semiconductor package assembly further comprises:
a first conductive bump disposed on the first surface of the first semiconductor die; and
a second conductive bump disposed on the second surface of the first semiconductor die;
wherein the second semiconductor die is electrically coupled to the first semiconductor die by the second interface.

2. The semiconductor package assembly as claimed in claim 1, wherein the first semiconductor die further comprises:
a semiconductor substrate; and
a first interconnect structure and a second interconnect structure disposed on opposite surfaces of the semiconductor substrate, wherein the first conductive bump is separated from the second conductive bump by the semiconductor substrate, the first interconnect structure and the second interconnect structure.

3. The semiconductor package assembly as claimed in claim 1, further comprising:
a first routing structure in contact with the first conductive bump, wherein the second semiconductor die is electrically coupled to the second interface of the first semiconductor die by the first conductive bump and the first routing structure.

4. The semiconductor package assembly as claimed in claim 3, further comprising:
a third conductive bump disposed on the first surface of the first semiconductor die and in contact with the first routing structure, wherein the third conductive bump is grounded.

5. The semiconductor package assembly as claimed in claim 4, wherein the third conductive bump is located in a central region of the first semiconductor die.

6. The semiconductor package assembly as claimed in claim 3, further comprising:
a second routing structure disposed below the second conductive bump; and
a first through via (TV) interconnect disposed beside the first semiconductor die and electrically coupled between the first routing structure and the second routing structure,
wherein the second routing structure is electrically coupled to the first interface of the first semiconductor die by the first TV interconnect and the first routing structure.

7. The semiconductor package assembly as claimed in claim 6, wherein the second routing structure is electrically coupled to the first interface of the first semiconductor die by the second conductive bump.

8. The semiconductor package assembly as claimed in claim 6, further comprising:
a second through via (TV) interconnect disposed beside the first semiconductor die and electrically coupled between the first routing structure and the second routing structure,
wherein the second semiconductor die is electrically coupled to the second routing structure by the first routing structure and the second TV interconnect.

9. The semiconductor package assembly as claimed in claim 8, wherein the second TV interconnect is a power TV interconnect.

10. The semiconductor package assembly as claimed in claim 1, wherein the first conductive bump is a signal bump, and the second conductive bump is a power bump.

11. The semiconductor package assembly as claimed in claim 6, further comprising:
a fan-out package comprising the first semiconductor die, the first routing structure and the second routing structure; and
a memory package comprising the third semiconductor die and stacked on the fan-out package, wherein the memory package comprises third conductive bumps arranged in groups and disposed on opposite edges of the memory package.

12. The semiconductor package assembly as claimed in claim 11, wherein the second interface is located in a central region of the first semiconductor die.

13. The semiconductor package assembly as claimed in claim 6, further comprising:
a fourth semiconductor die disposed between the first semiconductor die and the second routing structure, wherein the second routing structure is electrically coupled to the first interface of the first semiconductor die by the second conductive bump and the fourth semiconductor die.

14. The semiconductor package assembly as claimed in claim 13, wherein the fourth semiconductor die further comprises:
a third through via (TV) interconnect formed passing through the fourth semiconductor die, wherein the third TV interconnect overlaps and is electrically coupled to the second interface.

15. The semiconductor package assembly as claimed in claim 14, wherein the third TV interconnect is a power TV interconnect or a ground TV interconnect.

16. The semiconductor package assembly as claimed in claim 13, wherein the fourth semiconductor die further comprises:
a fourth through via (TV) interconnect formed passing through the fourth semiconductor die, wherein the fourth TV interconnect overlaps and is electrically coupled to the first interface.

17. A semiconductor package assembly, comprising:
a fan-out package, comprising:
a first routing structure and a second routing structure stacked on each other; and
a top semiconductor die disposed between the first routing structure and the second routing structure, wherein the top semiconductor die comprises:
a first interface arranged on a first edge of the top semiconductor die; and
a second interface arranged adjacent to the first interface, wherein the second interface is farther from the first edge of the top semiconductor die than the first interface; and
a memory package disposed on the fan-out package,
wherein a base is electrically coupled to the first interface by at least the second routing structure, and
the memory package is electrically coupled to the second interface by the first routing structure rather than the second routing structure.

18. The semiconductor package assembly as claimed in claim 17, wherein the base is electrically coupled to the second interface by the second routing structure rather than the first routing structure.

19. The semiconductor package assembly as claimed in claim 17, further comprising:
a conductive bump disposed offset from the second interface and in contact with the first routing structure, wherein the conductive bump is grounded.

20. The semiconductor package assembly as claimed in claim 17, wherein the fan-out package further comprises:
a bottom semiconductor die disposed between the top semiconductor die and the second routing structure, wherein the bottom semiconductor die comprises:
a through via (TV) interconnect overlapping and electrically coupled to the second interface.
